(19) United States
(12) Patent Application Publication
(10) Pub. No.: US 2013/0135948 A1
(43) Pub. Date: May 30, 2013

(54) SEMICONDUCTOR STORAGE DEVICE

(71) Applicant: Osamu HIRABAYASHI, Suginami-ku (JP)

(72) Inventor: Osamu HIRABAYASHI, Suginami-ku (JP)

(73) Assignee: KABUSHIKI KAISHA TOSHIBA, Tokyo (JP)

(21) Appl. No.: 13/420,898

(22) Filed: Mar. 15, 2012

(30) Foreign Application Priority Data
Nov. 30, 2011 (JP) 2011-262021

(51) Int. Cl. G11C 7/00

(52) U.S. Cl. 365/191

(57) ABSTRACT

A semiconductor storage device according to an embodiment includes: a memory cell in which data is stored; a word line through which the memory cell is selected in each row; a bit line through which a signal read from the memory cell is transmitted in each column; a speed detector that detects a read speed of the memory cell; and a voltage controller that controls at least one of a voltage at the word line and a cell power supply voltage of the memory cell based on the read speed of the memory cell.

### CROSS-REFERENCE TO RELATED APPLICATIONS

This application is based upon and claims the benefit of priority from Japanese Patent Application No. 2011-262021, filed on Nov. 30, 2011; the entire contents of which are incorporated herein by reference.

### FIELD

An embodiment disclosed herein relates generally to a semiconductor storage device.

### BACKGROUND

In an SRAM, a random variation of a characteristic of each transistor in a memory cell is increased with a progress of microfabrication of the memory cell. Therefore, an operating margin of the SRAM becomes small, and an operating voltage is hardly decreased or an operating speed is reduced.

### BRIEF DESCRIPTION OF THE DRAWINGS

FIG. 1 is a block diagram illustrating a schematic configuration of a semiconductor storage device according to an embodiment;

FIG. 2A is a view illustrating a relationship between a threshold voltage of each transistor of a memory cell in FIG. 1 and a memory cell leak current, FIG. 2B is a view illustrating a relationship between the threshold voltage of each transistor of the memory cell in FIG. 1 and a read current, and FIG. 2C is a view illustrating a relationship between the threshold voltage of each transistor of the memory cell in FIG. 1 and a disturb margin;

FIG. 3 is a block diagram illustrating an example of a configuration of a speed detector in FIG. 1;

FIG. 4 is a timing chart illustrating a waveform of a dummy bit line voltage of the speed detector in FIG. 3;

FIG. 5A is a view illustrating a relationship between a word line voltage and a cell power supply voltage and a count value in a power-saving mode of the semiconductor storage device in FIG. 1, and FIG. 5B is a view illustrating a relationship between the word line voltage and cell power supply voltage and the count value in a disturb margin improving mode of the semiconductor storage device in FIG. 1;

FIG. 6A is a view illustrating a relationship between the read current and the count value before and after trimming in the power-saving mode of the semiconductor storage device in FIG. 1, and FIG. 6B is a view illustrating a relationship between the leak current and the count value before and after the trimming in the power-saving mode of the semiconductor storage device in FIG. 1; and

FIG. 7A is a view illustrating a relationship between the read current and the count value before and after the trimming in the disturb margin improving mode of the semiconductor storage device in FIG. 1, and FIG. 7B is a view illustrating a relationship between the leak current and the count value before and after the trimming in the disturb margin improving mode of the semiconductor storage device in FIG. 1.

### DETAILED DESCRIPTION

According to a semiconductor storage device of an embodiment, a memory cell, a word line, a bit line, a speed detector, and a voltage controller are provided. Data is stored in the memory cell. The word line selects the memory cell in each row. The bit line transmits a signal, which is read from the memory cell, in each column. The speed detector detects a read speed of the memory cell. The voltage controller controls at least one of a voltage at the word line and a cell power supply voltage of the memory cell based on the read speed of the memory cell.

Hereinafter, a semiconductor storage device according to an embodiment will be described with reference to the drawings. However, the invention is not limited to the embodiment.

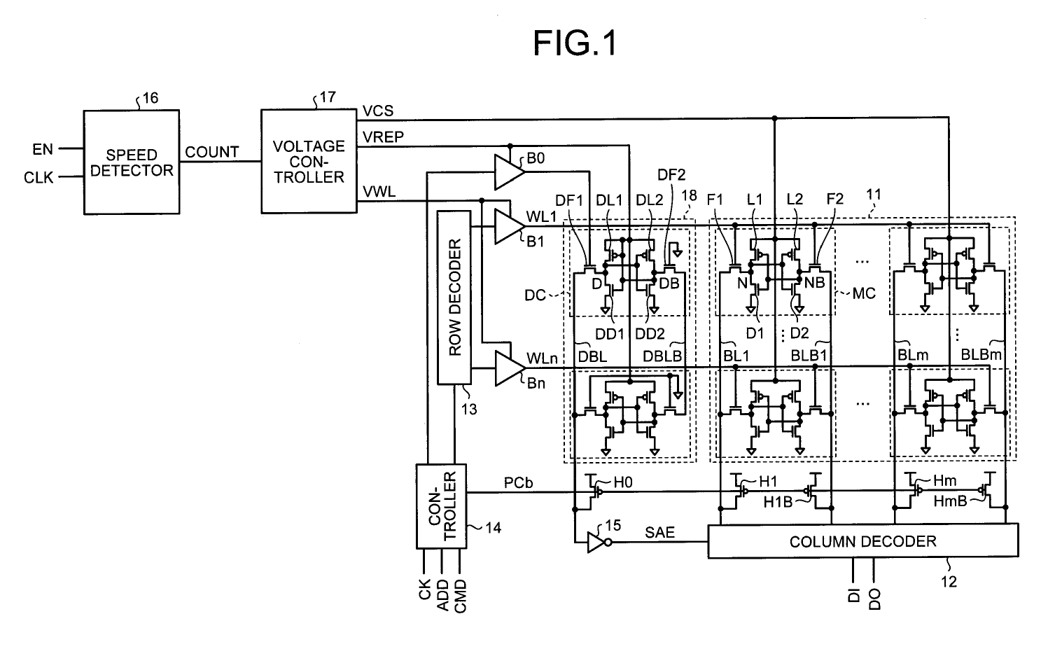

FIG. 1 is a block diagram illustrating a schematic configuration of a semiconductor storage device according to an embodiment.

Referring to FIG. 1, the semiconductor storage device includes a memory cell array 11, a column decoder 12, a row decoder 13, a controller 14, an inverter 15, a speed detector 16, a voltage controller 17, and a dummy cell array 18.

In the memory cell array 11, memory cells MC are two-dimensionally arrayed in a row direction and a column direction. The memory cell MC can complementarily store the data, and construct, for example, an SRAM.

In the memory cell array 11, each of word lines WL1 to WLn (N is a positive integer) is provided in a row to transmit a signal that select the row of the memory cell MC. In the memory cell array 11, each of bit lines BL1 to BLm and each of bit lines BLB1 to BLBm (M is a positive integer) are provided in a column to transmit and receive data to and from the memory cell MC.

The memory cells MC in the same row are commonly connected through each of the word lines WL1 to WLn. The memory cells MC in the same column are commonly connected through each of the bit lines BL1 to BLm and each of the bit lines BLB1 to BLBm. In reading and writing the data from and in the memory cell MC, each of the bit lines BL1 to BLm and each of the bit lines BLB1 to BLBm can be operated in a complementary way. For example, in reading and writing the data from and in the memory cell MC, the bit line BLBm is set to a low level when the bit line BLm is set to a high level, and the bit line BLBm is set to the high level when the bit line BLm is set to the low level. The bit lines BLm and BLBm can be pre-charged to the high level before the data is read from and written in the memory cell MC.

A pair of drive transistors D1 and D2, a pair of load transistors L1 and L2, and a pair of transmission transistors F1 and F2 are provided in the memory cell MC. A P-channel field effect transistor can be used as the load transistors L1 and L2, and an N-channel field effect transistor can be used as the drive transistors D1 and D2 and the transmission transistors F1 and F2.

A CMOS inverter is constructed by connecting the drive transistor D1 and the load transistor L1 in series, and another CMOS inverter is constructed by connecting the drive transistor D2 and the load transistor L2 in series. A flip-flop is constructed by cross coupling of an input and an output of the pair of CMOS inverters. Each of the word lines WL1 to WLn is connected to gates of the transmission transistor F1 and F2.

A connection point of a drain of the drive transistor D1 and a drain of the load transistor L1 constitutes a storage node N, and a connection point of a drain of the drive transistor D2 and a drain of the load transistor L2 constitutes a storage node NB.

Each of the bit lines BL1 to BLm is connected to the storage node N through the transmission transistor F1. Each of the bit lines BLB1 to BLBm is connected to the storage node NB through the transmission transistor F2.

Pre-charge transistors H1 to Hm are connected to the bit lines BL1 to BLm, respectively. Pre-charge transistors H1B to HmB are connected to the bit lines BLB1 to BLBm, respectively. The P-channel field effect transistor can be used as the pre-charge transistors H1 to Hm and H1B to HmB. A cell power supply voltage VCS is supplied to each memory cell MC. In the example in FIG. 1, the cell power supply voltage VCS is supplied to sources of the load transistors L1 and L2.

Dummy cells DC are disposed in the dummy cell array 18. The dummy cell DC can simulate an operation of the memory cell MC, and be constructed in the same way as the memory cell MC. The dummy cells DC are provided in the dummy cell array 18 in order that an influence of a characteristic fluctuation due to a production variation is reduced when the semiconductor storage device is used alone, whereby a random variation can be averaged. Dummy bit lines DBL and DBLB are provided in the dummy cell array 18 to transmit a signal read from the dummy cell DC.

A pair of dummy drive transistors DD1 and DD2, a pair of dummy load transistors DL1 and DL2, and a pair of dummy transmission transistor DF1 and DF2 are provided in the dummy cell DC. The P-channel field effect transistor can be used as the dummy load transistors DL1 and DL2, and the N-channel field effect transistor can be used as the dummy drive transistors DD1 and DD2 and the dummy transmission transistors DF1 and DF2.

A CMOS inverter is constructed by connecting the dummy drive transistor DD1 and the dummy load transistor DL1 in series, and another CMOS inverter is constructed by connecting the dummy drive transistor DD2 and the dummy load transistor DL2 in series. A flip-flop is constructed by cross coupling of an input and an output of the pair of CMOS inverters.

A connection point of a drain of the dummy drive transistor DD1 and a drain of the dummy load transistor DL1 constitutes a dummy node D, and a connection point of a drain of the dummy drive transistor DD2 and a drain of the dummy load transistor DL2 constitutes a dummy node DB.

The dummy node D is connected to the dummy bit line DBL through the dummy transmission transistor DF1, and the dummy node DB is connected to the dummy bit line DBLB through the t dummy transmission transistor DF2. A pre-charge transistor H0 is connected to the dummy bit line DBL. The P-channel field effect transistor can be used as the pre-charge transistor H0.

In some dummy cells DC in the dummy cell array 18, the controller 14 is connected to the gate of the dummy transmission transistor DF1 through a buffer B0, the gate of the dummy transmission transistor DF2 is grounded, and a node D is connected to the source of the dummy load transistor DL1. In the remaining dummy cells DC of the dummy cell array 18, the gates of the transmission transistors DF1 and DF2 are grounded. A dummy cell power supply voltage VREP is supplied to each dummy cell DC. In the example in FIG. 1, the dummy cell power supply voltage VREP is supplied to the sources of the dummy load transistors DL1 and DL2.

The column decoder 12 can select the column of the memory cell MC which is assigned by a column address. At this point, a sense amplifier circuit can be provided in the column decoder 12. The sense amplifier circuit detects the data stored in the memory cell MC based on the signal read from the memory cell MC to the bit lines BL and BLB. Read data DO can be output through the sense amplifier circuit. The column decoder 12 can write the data in the selected cell by complementarily changing potentials of the bit lines BL1 to BLm and BLB1 to BLBm of the selected row based on write data DI. The row decoder 13 can select the row of the memory cell MC which is assigned by a row address. Buffers B1 to Bn can drive the word lines WL1 to WLn based on the row selected by the row decoder 13, respectively. A word line voltage VWL is supplied as power supply voltages of the buffers B1 to Bn.

The controller 14 can control driving timings of the column decoder 12, row decoder 13, buffer B0, and pre-charge transistors H0 to Hm and H1B to HmB based on an address ADD and a command CMD. The inverter 15 can activate a sense amplifier enable signal SAE based on a potential at the dummy bit line DBL.

The speed detector 16 can detect a read speed of the memory cell MC. At this point, the speed detector 16 can simulate a read operation of the memory cell MC, and detect the read speed of the memory cell MC from the simulation result. The voltage controller 17 can control at least one of the word line voltage VWL and the cell power supply voltage VCS of the memory cell MC based on the read speed of the memory cell MC. The voltage controller 17 can control the dummy cell power supply voltage VREP in conjunction with the cell power supply voltage VCS. At this point, the dummy cell power supply voltage VREP can be set to a potential lower than the word line voltage VWL and the cell power supply voltage VCS by a given voltage. This is because the characteristic of the memory cell MC in which a threshold voltage is maximized (the read current is minimized) is reproduced in consideration of the random variation in characteristic of the memory cell MC. The dummy cell power supply voltage VREP can be set to a value that is lowered by the given voltage corresponding to the random variation.

An operation to set the word line voltage VWL and the cell power supply voltage VCS is performed before the read/write operation of the memory cell MC. In the operation to set the word line voltage VWL and the cell power supply voltage VCS, the speed detector 16 is operated according to a clock signal CLK by activating a test enable signal EN. For example, the speed detector 16 can repeatedly charge and discharge the dummy bit line that simulates capacitances of the bit lines BL1 to BLm. The number of repetition times of the charge and discharge is counted in one cycle of the clock signal CLK, and code information can be set based on a count value COUNT. In an inspection process before shipment, the code information may be stored in a fuse element or a register in a chip on which the semiconductor storage device in FIG. 1 is mounted.

The voltage controller 17 sets the word line voltage VWL and the cell power supply voltage VCS based on the code information, and the cell power supply voltage VCS is supplied to the sources of the load transistors L1 and L2 while the word line voltage VWL is supplied as the power supply voltage for the buffers B1 to Bn. The dummy cell power supply voltage VREP is supplied to the sources of the dummy load transistor DL1 and DL2 while supplied as the power supply voltage for the buffer B0.

A power-saving mode and a disturb margin improving mode can be set as a method for setting the word line voltage VWL and the cell power supply voltage VCS. In the power-saving mode, for the high read speed of the memory cell MC, both the word line voltage VWL and the cell power supply voltage VCS can be decreased compared with the low read speed of the memory cell MC. In the disturb margin improving mode, for the high read speed of the memory cell MC, the word line voltage VWL can be decreased while the cell power supply voltage VCS is kept constant compared with the low read speed of the memory cell MC. One of the power-saving mode and the disturb margin improving mode can be selected according to the variation in characteristic of the memory cell MC. The variation in characteristic of the memory cell MC can be estimated from a disturb defect incidence rate.

During a standby state, when the controller 14 activates the pre-charge signal PCb, the pre-charge transistors H0 to Hm and H1B to HmB are turned on to pre-charge the dummy bit line DBL and the bit lines BL1 to BLm and BLB1 to BLBm to the high level. At this point, the inverter 15 inverts the potential at the dummy bit line DBL, whereby the sense amplifier enable signal SAE is maintained at the low level while the sense amplifier circuit is deactivated.

In reading the data, the output of the buffer B0 rises at the time the word lines WL1 to WLm in which the row is selected by the row decoder 13 rise. Assuming that ‘0’ is stored in the storage node N of the selected cell while ‘1’ is stored in the storage node NB, when the word lines WL1 to WLm of the selected row rise, the transmission transistor F1 is turned on to pass a cell current through the bit lines BL1 to BLm of the selected column. Therefore, the potentials at the bit lines BL1 to BLm of the selected column are gradually decreased.

When the output of the buffer B0 rises, the dummy transmission transistor DF1 is turned on to pass a dummy current through the dummy bit line DBL. Therefore, the potential at the dummy bit line DBL is gradually decreased. At this point, the dummy bit line DBL simulates the capacitances of the bit lines BL1 to BLm, so that the dummy bit line DBL can simulate change situations of the potential at the bit lines BL1 to BLm.

When the potential at the dummy bit line DBL reaches a threshold of the inverter 15, a sense amplifier enable signal SAE rises to activate the sense amplifier circuit. In the sense amplifier circuit, the data stored in the memory cell MC is detected based on the signal transmitted through the bit lines BL1 to BLm, and output as the read data DO.

There is a relationship that a disturb margin is small for the high read speed of the memory cell MC while the disturb margin is large for the low read speed of the memory cell MC. On the other hand, the read speed of the memory cell MC is enhanced although the memory cell leak current is increased when the cell power supply voltage VCS is increased, and the read speed of the memory cell MC is reduced although the memory cell leak current is decreased when the cell power supply voltage VCS is decreased. The disturb margin is decreased although the data is easily written in the memory cell MC when the word line voltage VWL is increased, and the disturb margin is increased although the data is hardly written in the memory cell MC when the word line voltage VWL is decreased. The disturb margin is decreased although the read speed of the memory cell MC is enhanced when the word line voltage VWL is increased, and the disturb margin is increased although the read speed of the memory cell MC is reduced when the word line voltage VWL is decreased.

Therefore, the word line voltage VWL and the cell power supply voltage VCS are set based on the read speed of the memory cell MC, which allows the operating margin to be improved while the reduction of the read speed is suppressed.

It is believed that the margin exists for the high read speed of the memory cell MC. Therefore, by decreasing the cell power supply voltage VCS according to the margin of the read speed, the memory cell leak current can be decreased to reduce power consumption. The disturb margin can be increased by decreasing the word line voltage VWL according to the margin of the read speed.

On the other hand, it is believed that the margin of the memory cell leak current and the disturb margin exist for the low read speed of the memory cell MC. Therefore, the read speed of the memory cell MC can be enhanced by increasing the cell power supply voltage VCS according to the margin of the memory cell leak current. The read speed of the memory cell MC can also be enhanced by increasing the word line voltage VWL according to the disturb margin.

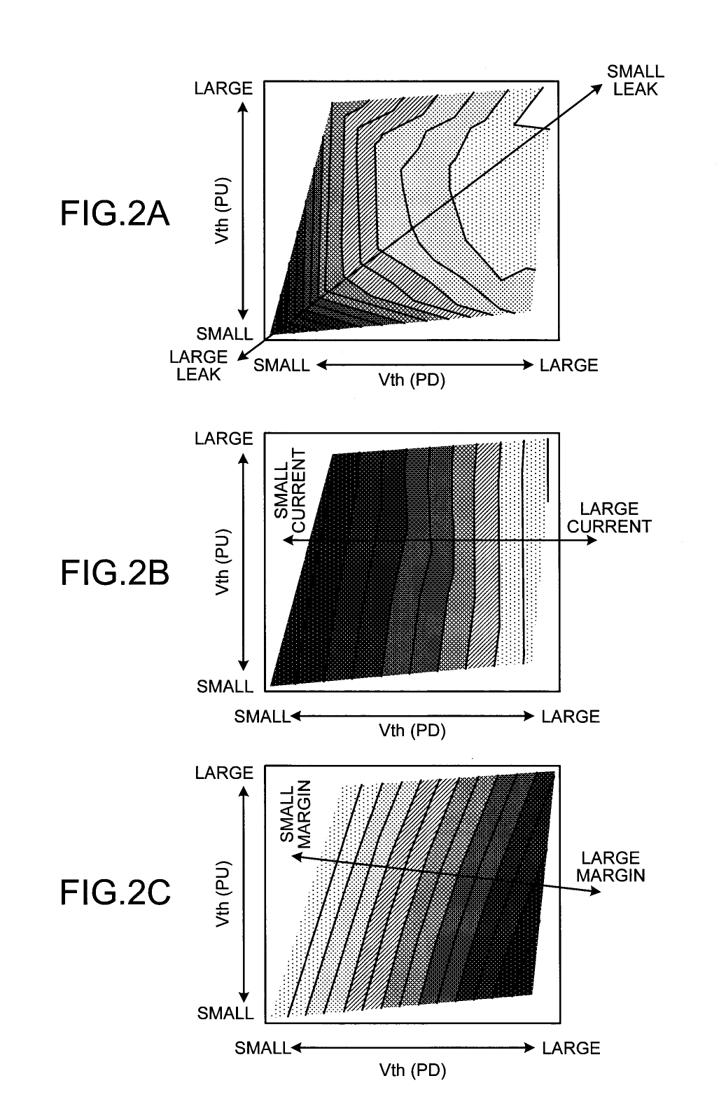

FIG. 2A is a view illustrating a relationship between the threshold voltage of each transistor of the memory cell in FIG. 1 and the memory cell leak current, FIG. 2B is a view illustrating a relationship between the threshold voltage of each transistor of the memory cell in FIG. 1 and the read current, and FIG. 2C is a view illustrating a relationship between the threshold voltage of each transistor of the memory cell in FIG. 1 and the disturb margin. In FIG. 2A to 2C, the symbol PD designates a pulldown-side transistor, and the symbol PU designates a pullup-side transistor.

Referring to FIG. 2A, in the SRAM, the memory cell leak current depends strongly on not only the threshold voltage of the pulldown-side transistor but also the threshold voltage of the pullup-side transistor.

On the other hand, referring to FIG. 2B, in the SRAM, the read current depends strongly only on the threshold voltage of the pulldown-side transistor. Referring to FIG. 2C, in the SRAM, the disturb margin depends strongly only on the threshold voltage of the pulldown-side transistor.

Therefore, there is a high correlation between the disturb margin and the read current. The chips are classified by the read current of the memory cell to set the word line voltage VWL and the cell power supply voltage VCS, which allows a balance between the read speed and the disturb margin to be established with high accuracy.

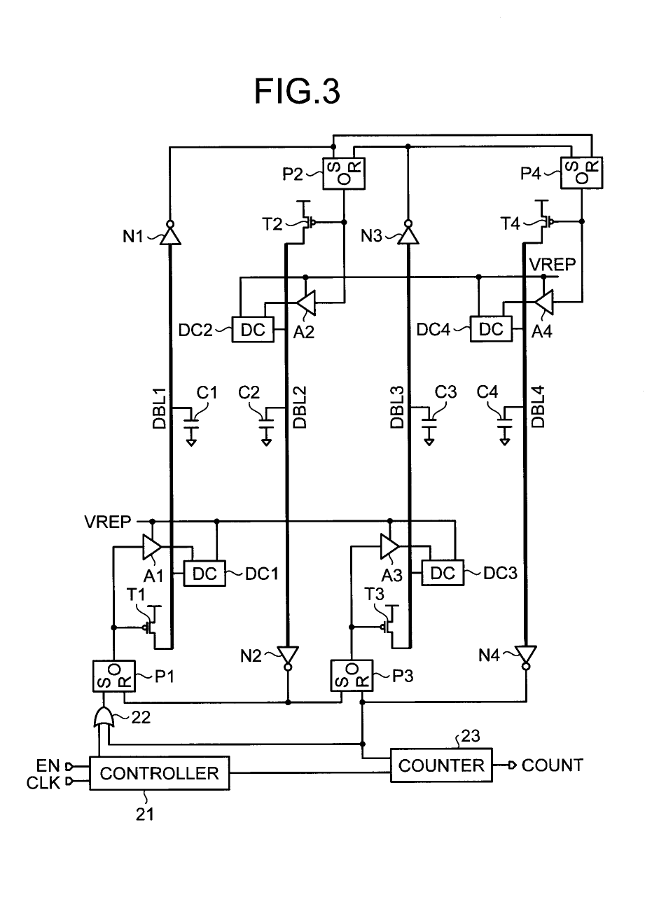

FIG. 3 is a block diagram illustrating an example of a configuration of the speed detector in FIG. 1. In FIG. 3, the speed detector 16 is described while the four dummy bit lines DBL1 to DBL4 are provided. Alternatively, K (K is a positive integer) dummy bit lines may be provided.

Referring to FIG. 3, a controller 21, an OR circuit 22, a counter 23, dummy bit lines DBL1 to DBL4, dummy cells DC1 to DC4, pre-charge transistors T1 to T4, flip-flops P1 to P4, capacitances C1 to C4, inverters N1 to N4, and buffers A1 to A4 are provided in the speed detector 16. The dummy cells DC1 to DC4 can be constructed in the same way as the dummy cell DC in FIG. 1. The dummy bit lines DBL1 to DBL4 can be constructed in the same way as the dummy bit line DBL in FIG. 1. The P-channel field effect transistor can be used as the pre-charge transistors T1 to T4. The capacitances C1 to C4 can correspond to the capacitance of the dummy bit line DBL in FIG. 1.

The dummy cells DC1 to DC4 are connected to the dummy bit lines DBL1 to DBL4 through the dummy transmission transistors DF1, respectively. The outputs of the buffers A1 to A4 are connected to the gates of the dummy transmission transistors DF1 of the dummy cells DC1 to DC4, respectively. The dummy cell power supply voltage VREP is supplied as the power supply voltage for the dummy cells DC1 to DC4 and the buffers A1 to A4.

One end of each of the dummy bit lines DBL1 to DBL4 is connected to a power supply potential through each of the pre-charge transistors T1 to T4. The other end of each of the dummy bit lines DBL1 to DBL4 is connected to a set terminal of each of the subsequent-stage flip-flops P1 to P4 through each of the inverters N1 to N4 while connected to a reset terminal of each of the preceding-stage flip-flops P1 to P4. However, for the initial-stage flip-flop P1, logical addition of the output of the inverter N4 and the output of the controller 21 is input through an OR circuit 22 instead of direct inputting the output of the inverter N4. The output of the inverter N4 is input to the counter 23.

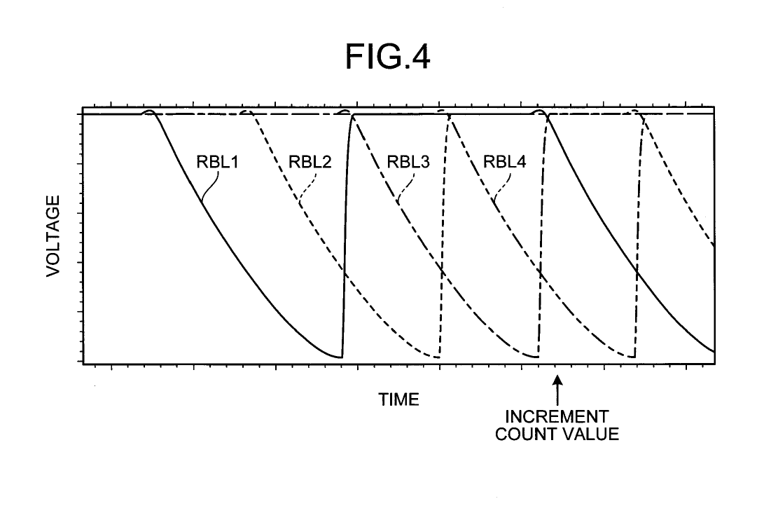

FIG. 4 is a timing chart illustrating a waveform of the dummy bit line voltage of the speed detector in FIG. 3.

Referring to FIG. 4, when the dummy bit lines DBL1 to DBL4 become the low level in an initial state, the output of the inverters N1 to N4 become the high level to reset the flip-flops P1 to P4. Therefore, the pre-charge transistors T1 to T4 are turned on to pre-charge the dummy bit lines DBL1 to DBL4 to the high level. During a shipment test, the flip-flop P1 is set when the test enable signal EN is activated in the controller 21. Therefore, the buffer A1 is activated while the pre-charge transistor T1 is turned off, and the dummy bit line DBL1 is discharged through the dummy cell DC1.

When the dummy bit line DBL1 is sufficiently discharged, the output of the inverter N1 is inverted to set the subsequent-stage flip-flop P1. Therefore, the buffer A2 is activated while the pre-charge transistor T2 is turned off, and the dummy bit line DBL2 is discharged through the dummy cell DC2.

When the dummy bit line DBL2 is sufficiently discharged, the output of the inverter N2 is inverted, and the preceding-stage flip-flop P1 is reset while the subsequent-stage flip-flop P3 is set. When the flip-flop P3 is set, the buffer A3 is activated while the pre-charge transistor T3 is turned off, and the dummy bit line DBL3 is discharged through the dummy cell DC3. When the flip-flop P1 is reset, the buffer A1 is deactivated while the pre-charge transistor T1 is turned on, and the dummy bit line DBL1 is pre-charged to the high level.

When the dummy bit line DBL3 is sufficiently discharged, the output of the inverter N3 is inverted, and the preceding-stage flip-flop P2 is reset while the subsequent-stage flip-flop P4 is set. When the flip-flop P4 is set, the buffer A4 is activated while the pre-charge transistor T4 is turned off, and the dummy bit line DBL4 is discharged through the dummy cell DC4. When the flip-flop P2 is reset, the buffer A2 is deactivated while the pre-charge transistor T2 is turned on, and the dummy bit line DBL2 is pre-charged to the high level.

When the dummy bit line DBL4 is sufficiently discharged, the output of the inverter N4 is inverted, and the preceding-stage flip-flop P3 is reset while the subsequent-stage flip-flop P1 is set. When the flip-flop P1 is set, the buffer A1 is activated while the pre-charge transistor T1 is turned off, and the dummy bit line DBL1 is discharged through the dummy cell DC1. When the flip-flop P3 is reset, the buffer A3 is deactivated while the pre-charge transistor T3 is turned on, and the dummy bit line DBL3 is pre-charged to the high level. When the output of the inverter N4 is inverted, the counter 23 increments the count value, and outputs the count value COUNT.

The above operations are repeated in the cycle of the clock signal CLK, and the count value COUNT is incremented every time the output of the inverter N4 is inverted. When discharge of the dummy cells DC1 to DC4 is enhanced, the time the output of the inverter N4 is inverted gains to increase the count value COUNT in the cycle of the clock signal CLK. When the discharge of the dummy cells DC1 to DC4 is enhanced, the read speed of the memory cell MC is enhanced. Therefore, the read speed of the memory cell MC can be detected by referring to the count value COUNT.

Accordingly, in the voltage controller 17 in FIG. 1, the word line voltage VWL and the cell power supply voltage VCS are set based on the count value COUNT, which allows the word line voltage VWL and the cell power supply voltage VCS to be set based on the read speed of the memory cell MC.

In the configuration in FIG. 3, because an interconnection resistance of the bit line, an interconnection capacitance, and a variation in threshold of the inverter are also reflected in addition to the read current, the SRAMs are classified so as to come close to the actual operating speed, and the word line voltage VWL and the cell power supply voltage VCS can be set such that the fluctuations of these characteristics are compensated.

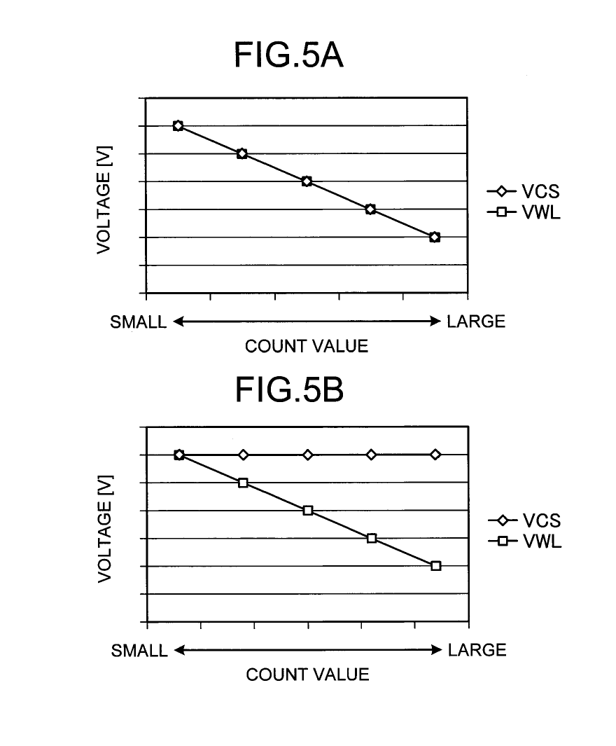

FIG. 5A is a view illustrating a relationship between the word line voltage and cell power supply voltage and the count value in the power-saving mode of the semiconductor storage device in FIG. 1, and FIG. 5B is a view illustrating a relationship between the word line voltage and cell power supply voltage and the count value in the disturb margin improving mode of the semiconductor storage device in FIG. 1.

Referring to FIG. 5A, the semiconductor storage device can be set in the power-saving mode in the case that it is not necessary to consider the disturb defect because of a not-so-large amount of random variation of the memory cell MC. In the power-saving mode, the word line voltage VWL and the cell power supply voltage VCS are decreased as the count value COUNT is increased. Therefore, for the chip having the large count value COUNT, the leak current can be reduced while the constant operating speed is maintained, and the power consumption can be suppressed.

On the other hand, referring to FIG. 5B, the semiconductor storage device can be set in the disturb margin improving mode in the case that it is necessary to consider yield degradation caused by the disturb defect because of a large amount of random variation of the memory cell MC. In the disturb margin improving mode, while the cell power supply voltage VCS is kept constant irrespective of the count value COUNT, the word line voltage VWL is decreased as the count value COUNT is increased. Therefore, for the chip having the large count value COUNT, the disturb defect can be reduced while the constant operating speed is maintained, and the yield of the chip can be improved. The power-saving mode and the disturb margin improving mode can properly be set according to an early stage and a maturation stage of production or a difference of production condition.

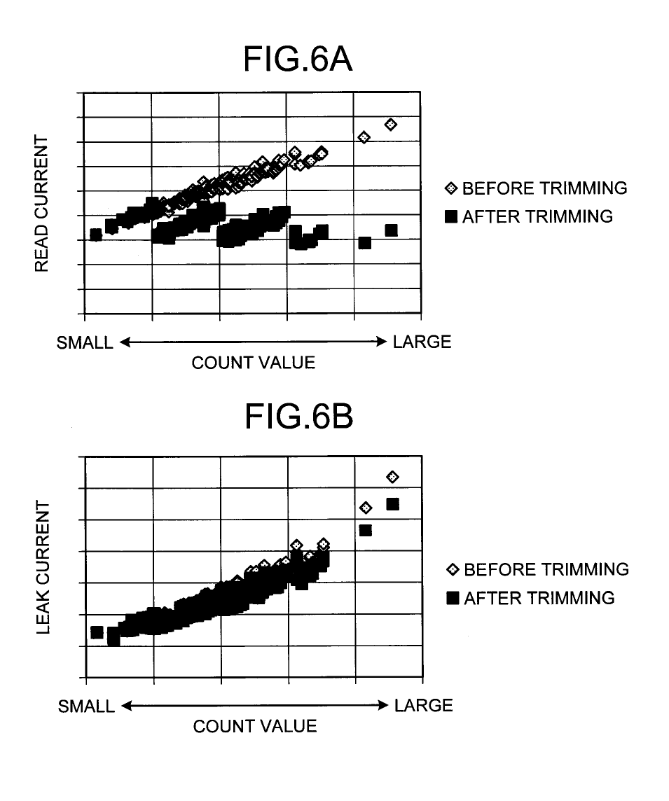

FIG. 6A is a view illustrating a relationship between the read current and the count value before and after trimming in the power-saving mode of the semiconductor storage device in FIG. 1, and FIG. 6B is a view illustrating a relationship between the leak current and the count value before and after the trimming in the power-saving mode of the semiconductor storage device in FIG. 1. “Before the trimming” means a time before the word line voltage VWL and the cell power supply voltage VCS are set according to the count value COUNT, and “after the trimming” means a time after the word line voltage VWL and the cell power supply voltage VCS are set according to the count value COUNT.

Referring to FIGS. 6A and 6B, in the power-saving mode in FIG. 5A, the word line voltage VWL and the cell power supply voltage VCS are decreased as the count value COUNT is increased, which allows the leak current to be reduced while the read current is kept constant.

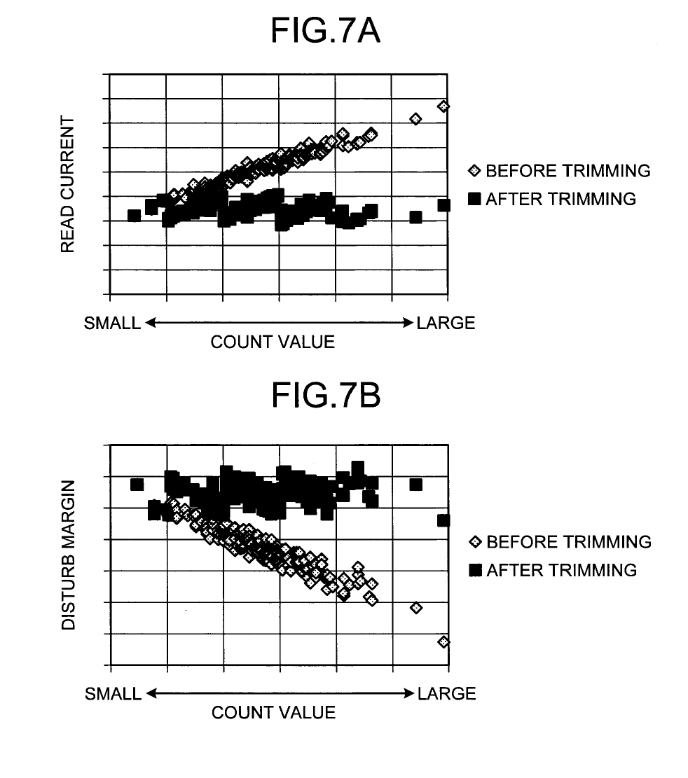

FIG. 7A is a view illustrating a relationship between the read current and the count value before and after the trimming in the disturb margin improving mode of the semiconductor storage device in FIG. 1, and FIG. 7B is a view illustrating a relationship between the leak current and the count value before and after the trimming in the disturb margin improving mode of the semiconductor storage device in FIG. 1.

Referring to FIGS. 7A and 7B, in the disturb margin improving mode in FIG. 5B, while the cell power supply voltage VCS is kept constant irrespective of the count value COUNT, the word line voltage VWL is decreased as the count value COUNT is increased. Therefore, the disturb margin can be improved while the read current is kept constant.

In the above embodiment, the word line voltage VWL and the cell power supply voltage VCS are set based on the read speed of the memory cell MC. Alternatively, a well bias or a substrate bias of the transistor of the memory cell MC may be controller based on the read speed of the memory cell MC.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell configured to store data;
a word line configured to select a row corresponding to the memory cell;
a bit line configured to transmit a signal read from a column corresponding to the memory cell;
a speed detector configured to detect a read speed of the memory cell; and
a voltage controller configured to control at least one of a voltage at the word line and a cell power supply voltage of the memory cell based on the read speed of the memory cell.

2. The semiconductor storage device of claim 1, wherein the voltage controller is configured to lower both the voltage at the word line and the cell power supply voltage in a case of a high read speed.

3. The semiconductor storage device of claim 1, wherein the voltage controller is configured to lower the voltage at the word line while keeping the cell power supply voltage constant in a case of a high read speed.

4. The semiconductor storage device of claim 1, wherein the voltage controller comprises:
a power-saving mode where both the voltage at the word line and the cell power supply voltage are lowered in a case of a high read speed; and
a disturb margin improving mode where the voltage at the word line is lowered while keeping the cell power supply voltage constant in the case of the high read speed, and
wherein one of the power-saving mode and the disturb margin improving mode is selected based on a variation in a characteristic of the memory cell.

5. The semiconductor storage device of claim 1, wherein the memory cell comprises:
a first CMOS inverter comprising a first drive transistor and a first load transistor connected in series;
a second CMOS inverter comprising a second drive transistor and a second load transistor connected in series;
a first transmission transistor connected between a first storage node and a first bit line, the first storage node located at a connection point of the first drive transistor and the first load transistor; and
a second transmission transistor connected between a second storage node and a second bit line, the second storage node located at a connection point of the second drive transistor and the second load transistor,
an input and an output of each of the first CMOS inverter and the second CMOS inverter cross-coupled, and
a gate of the first transmission transistor and a gate of the second transmission transistor connected to the word line.

6. The semiconductor storage device of claim 1, wherein the speed detector comprises:
a dummy cell configured to simulate an operation of the memory cell; and
a dummy bit line configured to transmit a signal read from the dummy cell, and
wherein the read speed of the memory cell is detected based on a potential at the dummy bit line when the signal is read from the dummy cell.

7. The semiconductor storage device of claim 6, wherein the speed detector is configured to count the number of repetition times of a charge and a discharge of the dummy bit line in one cycle of a clock signal and set code information based on the count value, and
the voltage controller is configured to set the voltage at the word line and the cell power supply voltage of the memory cell based on the code information.

8. The semiconductor storage device of claim 6, wherein the voltage controller is configured to control a dummy cell power supply voltage of the dummy cell in conjunction with the cell power supply voltage.

9. The semiconductor storage device of claim 8, wherein the voltage controller is configured to set the dummy cell power supply voltage to a potential lower than the word line voltage and the cell power supply voltage by a first voltage.

10. The semiconductor storage device of claim 9, wherein the voltage controller is configured to set the dummy cell power supply voltage to a value lower than the word line voltage and the cell power supply voltage by the first voltage corresponding to a random variation of the memory cell.

11. The semiconductor storage device of claim 6, wherein the speed detector comprises:
N (N is a positive integer) dummy bit lines;
N dummy cells configured to discharge the dummy bit line;
a pre-charge transistor configured to pre-charge the dummy bit lines;
N flip-flops configured to discharge the dummy bit lines through the dummy cells while turning off the pre-charge transistor based on a potential at a preceding-stage dummy bit line, and stop the discharge of the dummy bit lines of the dummy cells while turning on the pre-charge transistor based on a potential at a subsequent-stage dummy bit line;
a counter configured to count the number of repetition times of a charge and a discharge of the dummy bit line.

12. The semiconductor storage device of claim 1, further comprising a row decoder configured to select the word line where the voltage at the word line is supplied.

13. The semiconductor storage device of claim 12, further comprising a column decoder configured to select a column of the memory cell assigned by a column address.

14. The semiconductor storage device of claim 13, wherein the column decoder comprises a sense amplifier configured to detect data stored in the memory cell based on the signal read from the memory cell to the bit line.

15. The semiconductor storage device of claim 14, further comprising a dummy cell configured to set a time that the sense amplifier circuit is activated.

16. The semiconductor storage device of claim 15, further comprising a pre-charge transistor configured to pre-charge the bit line.

17. The semiconductor storage device of claim 11, wherein the voltage controller comprises:
a power-saving mode where both the voltage at the word line and the cell power supply voltage are lowered in a case of a high read speed; and
a disturb margin improving mode where the voltage at the word line is lowered while keeping the cell power supply voltage constant in the case of the high read speed, and
wherein one of the power-saving mode and the disturb margin improving mode is selected based on a variation in a characteristic of the memory cell.

18. The semiconductor storage device of claim 17, wherein the voltage controller is configured to set the semiconductor storage device in the power-saving mode when a random variation amount of the memory cell is not more than a first value, and the voltage controller is configured to set the semiconductor storage device in the disturb margin improving mode when the random variation amount of the memory cell is more than the first value.

19. The semiconductor storage device of claim 18, wherein the voltage controller is configured to decrease the word line voltage and the cell power supply voltage as the count value of the counter is increased in the power-saving mode.

20. The semiconductor storage device of claim 18, wherein the voltage controller is configured to keep the cell power supply voltage constant irrespective of the count value of the counter, and decrease the word line voltage as the count value of the counter is increased in the disturb margin improving mode.
